(19) United States
(12) Patent Application Publication
(10) Pub. No.: US 2007/0181065 A1
(43) Pub. Date: Aug. 9, 2007

(54) ETCH RESISTANT HEATER AND ASSEMBLY THEREOF

(75) Inventors: Akinobu Otaka, Toyonaka-city (JP); Takeshi Higuchi, Kobe-city (JP); Sridhar Ramaprasad Prasad, Bangalore (IN); Wei Fan, Middleburg Heights, OH (US); Marc Schaepkens, Medina, OH (US); Douglas A. Longworth, Brecksville, OH (US)

Correspondence Address: MOMENTIVE PERFORMANCE MATERIALS INC.-Quartz;c/o DILWORTH & BARRESE, LLP, 333 Earle Ovington Blvd., Uniondale, NY, 11553, US

(73) Assignee: General Electric Company, Schenectady, NY (US)

(21) Appl. No.: 11/550,785

(22) Filed: Oct. 18, 2006

Related U.S. Application Data
(60) Provisional application No. 60/771,745, filed on Feb. 9, 2006.
(60) Provisional application No. 60/744,741, filed on Apr. 12, 2006.

(51) Int. Cl. C23C 16/00

(52) U.S. Cl. 118/725; 118/723 R

(57) ABSTRACT

An etch resistant heater for use in a wafer processing assembly with an excellent ramp rate of at least 20° C. per minute. The heater is coated with a protective overcoating layer allowing the heater to have a radiation efficiency above 70% at elevated heater temperatures of >1500° C., and an etch rate in NF₃ at 600° C. of less than 100 A/min.

### CROSS-REFERENCE TO RELATED APPLICATIONS

This application claims the benefits of U.S. Patent Application Ser. No. 60/771,745, with a filing date of Feb. 9, 2006; and U.S. Patent Application Ser. No. 60/744741 with a filing date of Apr. 12, 2006, which patent applications are fully incorporated herein by reference.

### FIELD OF THE INVENTION

The invention relates generally to a heater and a heater assembly, for use in the fabrication of electronic devices.

### BACKGROUND OF THE INVENTION

The process for fabrication of electronic devices, including integrated circuits (ICs), micro-electromechanical systems (MEMs), optoelectronic devices, flat panel display devices, comprises a few major process steps including the controlled deposition or growth of materials and the controlled and often selective removal or modification of previously deposited/grown materials. Chemical Vapor Deposition (CVD) is a common deposition process, which includes Low Pressure Chemical Vapor Deposition (LPCVD), Atomic Layer Chemical Vapor Deposition (ALD or ALCVD), Thermal Chemical Vapor Deposition (TCVD), Plasma Enhanced Chemical Vapor Deposition (PECVD), High Density Plasma Chemical Vapor Deposition (HDP CVD), Expanding Thermal Plasma Chemical Vapor Deposition (ETP CVD), Thermal Plasma Chemical Vapor Deposition (TPCVD), and Metal Organic Chemical Vapor Deposition (MOCVD) etc.

In some of the CVD processes, one or more gaseous reactants are used inside a reactor under low pressure and high temperature conditions to form a solid insulating or conducting layer on the surface of a semiconductor wafer, which is located on a substrate holder placed in a reactor. The substrate holder/susceptor in the CVD process could function as a heater, which typically contains at least one heating element to heat the wafer; or could function as an electrostatic chuck (ESC), which comprises at least one electrode for electro-statically clamping the wafer; or could be a heater/ESC combination, which has electrodes for both heating and clamping. After a deposition of a film of predetermined thickness on the silicon wafer, there is a spurious deposition on other exposed surfaces inside the reactor, including the reactor walls, reactor windows, gas injector surfaces, exhaust system surfaces, and the substrate holder surfaces exposed to the deposition process. This spurious deposition could present problems in subsequent depositions, and is therefore periodically removed with a cleaning process, i.e. in some cases after every wafer and in other cases after a batch of wafers has been processed. Common cleaning processes in the art include atomic fluorine based cleaning, fluorocarbon plasma cleaning, sulfur hexafluoride plasma cleaning, nitrogen trifluoride plasma cleaning, and chlorine trifluoride cleaning. In the cleaning process, the reactor components, e.g., walls, windows, the substrate holder and assembly, etc., are expected to be corroded/attacked away.

Besides the highly corrosive environment in the CVD processes, these processes are also heated up to a high temperature, i.e., over 1000° C. for silicon wafers. Additionally in these processes, the wafers must simultaneously be maintained at prescribed temperature uniformity. In most applications, the heat is transferred to the wafer through conduction, when the surface to be heated is placed in direct physical contact with the heating element. However, it is not always practical in some applications to establish physical contact between the surface to be heated and the heating element. Metal Organic Chemical Vapor Deposition (MOCVD) process is widely used for thin film growth, a critical step in high technology microfabrications. In MOCVD application, the system is placed in a very high vacuum environment with the wafers being placed on a rotating surface (susceptor) to improve the uniformity of the epilayer. Hence, this rotating susceptor cannot directly touch the heating element. The heat transfer from the heating element to the wafers is not possible both by convection (due to vacuum conditions) and by conduction (due to non-contact). Thus, radiation (or using a radiant heating element) is the only available mechanism for heat transfer. Additionally, the required temperature range of the graphite susceptor on which the wafers are supported can be as high as over 1500° C.

In one embodiment of the prior art, etch-resistant materials are used for components such as the susceptors/heater/substrate holder. At the high temperature in a CVD process, the erosion rate of etch-resistant materials in the prior art would increase exponentially. For this reason, the prior art heaters are ramped down, for example, from the 600-1500° C. at which deposition might occur, to 400° C. at which the cleaning can happen. This approach will increase the lifetime of the heater but reduces the overall throughput substantially.

Thermal modules designed for MOCVD applications typically use high intensity lamps as the radiant heating element. These lamps allow fast heating because of their low thermal mass and rapid cooling. They can also be turned off instantly, without a slow temperature ramp down. Heating by high intensity lamps does not always give the desired temperature uniformity on the wafer surface. Multi-zone lamps may be used to improve temperature uniformity, but they increase costs and maintenance requirements. In addition, many lamps use a linear filament, which makes them ineffective at providing uniform heat to a round wafer. In some thermal modules for MOCVD applications, resistive substrate heaters are used as the radiant heating element to provide a stable and repeatable IS heat source. Most resistive heaters in the prior art tend to have a large thermal mass, which makes them unsuitable for high temperature applications of >1500° C. on the graphite susceptor.

One frequently used etch-resistant material for resistive substrate heaters (as well for non-heated substrate holders) is aluminum nitride, with sintered aluminum nitride (AlN) being most common. Unfortunately, the sintered AlN substrate holders of the prior art suffer from an important limitation, namely they can only be heated or cooled at a rate of <20° C./min. If ramped any faster, the ceramic will typically crack. Furthermore, only moderate temperature differentials can be sustained across a substrate surface before the ceramic will crack.

U.S. Pat. No. 6,140,624 discloses resistive heaters having an outer coating selected from the group consisting of silicon carbide and boron carbide, for a radiation efficiency of >80%. However, for very high temperature applications, i.e., where the required heater temperatures are >1500° C., a silicon carbide coating will not work well since silicon carbide decomposes at such high temperatures. On the other hand, heaters with a boron carbide outer coating layer is technically feasible but not commercially practical to manufacture.

The invention relates to an improved apparatus, e.g., a ceramic heater or a wafer processing assembly such as a thermal module wherein the improved heater is employed, the apparatus has an excellent thermal efficiency for heating wafers in thermal modules to the required high temperatures. The apparatus of the invention maintains good temperature uniformity on the wafers with minimum risk of degradation and decomposition in operations, and with excellent etch resistant properties for extended life in operations.

### SUMMARY OF THE INVENTION

In one aspect, the invention relates to an apparatus such as radiant heater, which can be used as part of a thermal module, with a radiation efficiency above 70% at elevated heater temperatures of >1500° C. In one embodiment, the apparatus comprises a base substrate comprising boron nitride, a heating element of pyrolytic graphite superimposed on one side of the base substrate and having a patterned geometry forming a pair of contact ends. A first outer coating surrounding this heating element is composed of at least one of a nitride, carbide, carbonitride or oxynitride of elements selected from a group consisting of B, Al, Si, Ga, refractory hard metals, transition metals, and combinations thereof, and an overcoating layer which surrounds the first outer coating with a radiation efficiency of above 70% and preferably at least 80% at elevated heater temperatures of greater than 1500° C.

In one embodiment, the overcoating layer has a planar thermal conductivity of at least 3 times the planer thermal conductivity of the first outer coating so that it also improves the temperature uniformity on the radiating surface of the heater, which then has a direct improvement on the thermal uniformity of the wafers. In a third embodiment, the overcoating layer comprises pyrolytic graphite.

In another aspect, the invention relates to a thermal module for use in high temperature semiconductor processes such as MOCVD. The thermal module contains the above-defined heater as the radiant heating element. In one embodiment, the module further includes a reflector stack comprising a high reflective material placed below the heater to better conserve the heat generated. Additional tubular reflector shields and covers may also be added to help even better conservation of the heater power.

### BRIEF DESCRIPTION OF THE DRAWINGS

FIGS. 1A-1C are cross-sectional views showing one embodiment of a heater, as it is being formed in various process steps, with a pyrolytic graphite overcoat layer on one surface of the heater.

FIG. 1D-1E are cross sectional views of various embodiments of a susceptor.

FIG. 1F-1H are cross section views of various embodiments of a heater having a coil shape (as formed from a coil-shaped substrate).

FIGS. 2A-2B are cross-sectional views showing a second embodiment of a ceramic heater, as it is being formed in various process steps, with a pyrolytic graphite overcoating layer protecting the entire heater structure.

FIG. 3A is a top view of one embodiment of a ceramic heater, wherein all the top coating layers are removed showing the geometrical pattern of the pyrolytic graphite heating element. FIG. 3B is a cross-section view of another embodiment of a heater assembly, wherein with a substrate holder having upper and lower relatively flat surfaces and a shaft extending substantially transverse to the substrate holder.

FIG. 4 is a cross-sectional view showing a thermal module employing a heater of the prior art, for use in a computational fluid dynamics (CFD) calculation to examine the heater surface temperature as the wafer is heated up to a temperature of 1500° C.

FIG. 5 is a cross-sectional view showing a thermal module employing a heater of FIGS. 1A-1C, for use in a computational fluid dynamics (CFD) calculation to examine the surface temperature of the heater of the invention as the wafer is heated up to a temperature of 1500° C.

FIG. 6 is a graph illustrating the etch rate of various materials in a NF₃ environment at room temperature.

FIG. 7 is a graph comparing the etch rate of one embodiment of the overlayer of the heater with other materials in the prior, including pyrolytic boron nitride and sintered aluminum nitride at 400° C.

FIG. 8 is a photograph (¼ magnification) of a prior art heater with a pyrolytic boron nitride coating after being etched.

FIG. 9A is a diagram of an experimental set-up for the heater ramping tests comparing a heater in the prior art and one embodiment of a heater in the present invention, a PG over-coated PBN heater. FIG. 9B is a close up sectional view of the heater.

FIGS. 10A and 10B are graphs comparing heater temperatures and achieved susceptor temperatures obtained from a heater in the prior art and one embodiment of a heater in the present invention, a PG over-coated PBN heater.

FIG. 11 is a graph comparing the etch rates of the overcoating layer of the heater invention after etching at 400° C., after 1 hour and 5 hours.

FIG. 12 is a graph comparing the etch rates of the overcoating layer of the heater invention after etching at 600° C., after continuous and pulsed etching for 1 hour.

### DESCRIPTION OF THE INVENTION

As used herein, approximating language may be applied to modify any quantitative representation that may vary without resulting in a change in the basic function to which it is related. Accordingly, a value modified by a term or terms, such as “about” and “substantially,” may not to be limited to the precise value specified, in some cases.

As used herein, the term “heater” is not limited to a ceramic heater, but can be used to indicate a “susceptor,” a “wafer holder,” or a “heater/electrostatic chuck combination,” for use in heating or supporting a silicon wafer in a thermal module, batch furnace, CVD processing chamber or reactor.

As used herein, “heater assembly” is used interchangeably with “thermal module,” “batch furnace,” “CVD processing chamber,” or “reactor,” referring to an assembly wherein electronic devices or wafers are processed.

“Wafer substrates” or “substrates” as used herein are in the plural form, but the terms are used to indicate one or multiple substrates can be used, and that “wafer” may be used interchangeably with “substrate” or “wafer substrate.” Likewise, “heaters,” “susceptors,” “electrodes” or “heating elements” may be used in the plural form, but the terms are used to indicate that one or multiple items may be used.

Hereinafter, the invention will be explained in more detail starting with the innermost layer of the heater going outwards, i.e., from the base substrate, the electrode, the first protective coating layer, to the top overcoat layer.

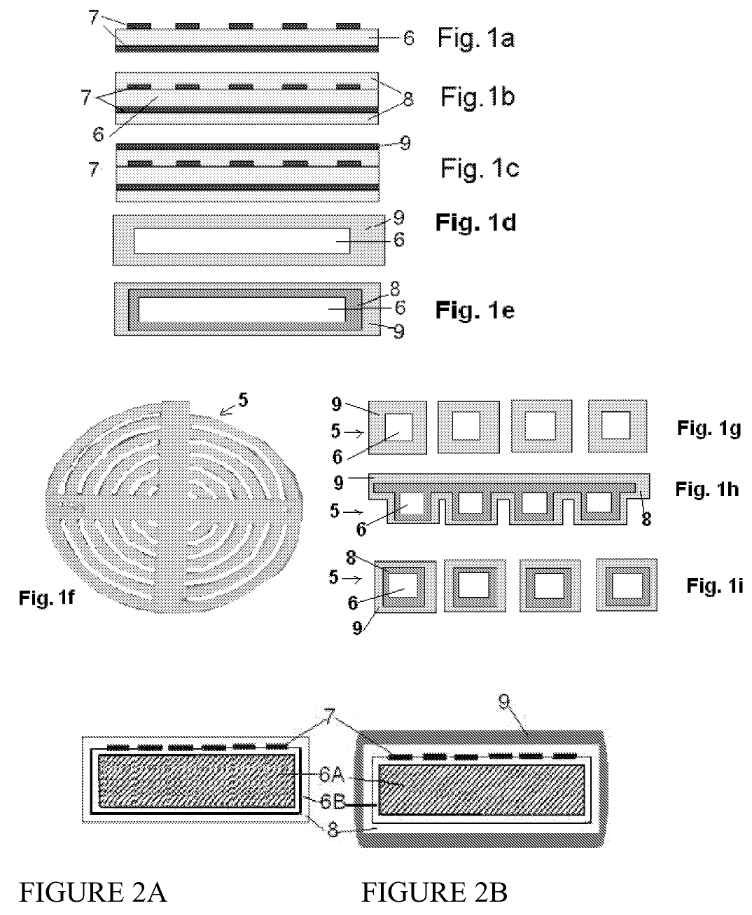

Base Substrate: In one embodiment, the apparatus comprises a base substrate consisting of a single layer as illustrated in FIG. 1A, for a base substrate 6 in the form of a disk having the required integrity as well as the machinability into desired shapes. In another embodiment as illustrated in FIG. 1F, the base substrate 6 is not in a contiguous disk form, but patterned into a coil shaped for a coil heater 5. FIGS. 1G-1H are cross-sections of various embodiments of a heater having a coil-shaped base substrate.

The base substrate 6 is characterized as having excellent physical properties such as heat resistance and strength. In one embodiment, the base substrate 6 comprises one of graphite; refractory metals such as W, transition metals, rare earth metals and alloys; and mixtures thereof In another embodiment, the base substrate 6 is a sintered material, further comprising sintering aids, metal or carbon dopants and impurities. In another embodiment, the base substrate 6 comprises a sintered material including at least one of oxide, nitride, carbide, carbonitride or oxynitride of elements selected from a group consisting of B, Al, Si, Ga, refractory hard metals, transition metals; oxide, oxynitride of aluminium; and combinations thereof. In yet another embodiment, the base substrate 6 comprises a material characterized as having excellent machinability characteristics, such as a blend of boron nitride and aluminium nitride, giving the base substrate the required integrity as well as the machinability into desired shapes.

The base substrate 6 in one embodiment consists any one of boron nitride sintered body, a mixed sintered body of boron nitride and aluminium nitride. In a second embodiment, the base substrate 6 comprises a pyrolytic boron nitrite plate as formed via a CVD process. In one embodiment as illustrated in FIGS. 1D and 1E wherein the apparatus is in the form of a susceptor, the base substrate 6 comprises bulk graphite.

In yet another embodiment as illustrated in FIG. 2A, the base substrate 6 comprises a core base plate 6A coated with a first overcoat layer 6B. The layer 6B comprises at least a nitride, carbide, carbonitride or oxynitride of elements selected from a group consisting of B, Al, Si, Ga, refractory hard metals, transition metals, and combinations thereof. In one embodiment, the first overcoat layer 6B comprises pBN, for a protective layer that is stable up to high temperature of 1500° C. or more. The first overcoat layer 6B may be deposited on the base plate 6A by processes including but not limited to expanding thermal plasma (ETP), ion plating, chemical vapor deposition (CVD), plasma enhanced chemical vapor deposition (PECVD), metal organic chemical vapor deposition (MOCVD) (also called Organometallic Chemical Vapor Deposition (OMCVD)), metal organic vapor phase epitaxy (MOVPE), physical vapor deposition processes such as sputtering, reactive electron beam (e-beam) deposition, and plasma spray. Exemplary processes are ETP, CVD, and ion plating. The thickness of the first overcoat layer 6B may be varied depending upon the application and the process used, e.g., CVD, ion plating, ETP, etc, varying from 1 μm to a few hundred μm, depending on the application. In one embodiment, the coating 6B has a thickness of greater than or equal to about 10 micrometers (μm). In another embodiment, the protective coating thickness is greater than or equal to about 50 μm. In a third embodiment, the thickness is greater than or equal to about 100 μm. In yet another embodiment, the thickness is less than or equal to about 500 μm.

Electrode Layer/Heating Element: In embodiments wherein the apparatus is in the form of a ceramic heater, the apparatus further comprises an electrode layer/heating element 7 as illustrated in FIGS. 1A. In one embodiment, the electrode 7 consists of any one of gold, platinum, silver, a mixture of gold or platinum and silver, titanium, tungsten, tantalum, pyrolytic graphite, and pyrolytic graphite containing boron and/or boron carbide, being able to withstand temperatures of 1500° C. or more.

In one embodiment, the electrode 7 has a thickness of about 5-500 μm thick. In a second embodiment, it has a thickness of 10-300 μm. In a third embodiment, the electrode layer has a thickness of 30-200 μm. In a fourth embodiment, the thickness of the electrode 7 is in the range of 1 to 30 μm. In a fifth embodiment, from 1 to 10 μm.

In one embodiment, the pattern width of the electrode 7 is in the range of 0.1 to 20 mm. In a second embodiment, the pattern width is 0.1 to 5 mm. In a third embodiment, from 5 to 20 μm.

In one embodiment, the electrode layer 7 covers either top or bottom surface of the base substrate. In another embodiment, the electrode layer 7 covers both top and bottom surfaces of the base substrate 6 as illustrated in FIGS. 1A and 1B.

Different methods can be used to deposit the electrode layer 7 onto the base substrate 6, including physical vapour deposition (PVD), sputtering, ion plating, plasma-supported vapor deposition, or chemical vapour deposition.

In one embodiment, either the top or bottom electrode layer 7 (or both top and bottom electrode layers) is machined into a pre-determined pattern, e.g., in a spiral or serpentine geometry as shown in FIG. 2A, so as to form an electrical flow path in the form of an elongated continuous strip of pyrolytic graphite having opposite ends (not shown). The electrical flow path can be one of a spiral pattern, a serpentine pattern, a helical pattern, a zigzag pattern, a continuous labyrinthine pattern, a spirally coiled pattern, a swirled pattern, a randomly convoluted pattern, and combinations thereof. The forming of the electrical pattern of the heating zones, i.e., an electrically isolated, resistive heater path, may be done by techniques known in the art, including but not limited to micro machining, micro-brading, laser cutting, chemical etching, or e-beam etching.

The electrode layer 7 forms a heating element upon connection to an external power supply (not shown). In one embodiment, the electrode 7 defines a plurality of electrode zones for independent controlled heating or cooling of objects of varying sizes, each zone comprising a one or more electrode elements 7.

Protective Coating Layer. In a heater embodiment, the base substrate having an electrode layer is next coated with a first protective coating layer 8 as illustrated in FIGS. 1B and 1C. In the embodiment of a susceptor as shown in FIG. 1E, the first protective coating layer 8 is applied directly onto the base substrate 6.

The protective coating layer 8 comprises at least one of: a nitride, carbide, carbonitride or oxynitride of elements selected from a group consisting of B, Al, Si, Ga, refractory hard metals, transition metals, and combinations thereof; a high thermal stability zirconium phosphates having an NZP structure of NaZr₂ (PO₄)₃; a glass-ceramic composition containing at least one element selected from the group consisting of elements of the group 2a, group 3a and group 4a of the periodic table of element; a mixture of SiO₂ and a plasma-resistant material comprising an oxide of Y, Sc, La, Ce, Gd, Eu, Dy, or the like.

In one embodiment, the nitride is selected from one of pyrolytic boron nitride (pBN), carbon doped pBN, aluminium nitride (AlN), carbon doped AlN, oxygen-doped AlN, aluminium oxide, aluminium oxynitride, silicon nitride, or complexes thereof. As used herein, aluminium nitride refers to AlN, AlON, or combinations thereof In one embodiment, the protective coating layer 8 is a single layer of AlN, AlON, Al₂O₃ or combinations thereof. In another embodiment, it is a multi-layer comprising multiple coatings of the same material, e.g., AlN, AlON, Al₂O₃, etc., or multiple different layers of AlN, AlON, pBN, SiN, etc., coated in succession.

The protective coating layer 8 may be deposited by any of ETP, ion plating, CVD, PECVD, MOCVD, OMCVD, MOVPE, ion plasma deposition, physical vapor deposition processes such as sputtering, reactive electron beam (e-beam) deposition, plasma spray, and combinations thereof. Exemplary processes are ETP, CVD, and ion plating.

The thickness of the protective coating layer 8 varies depending upon the application and the process used, e.g., CVD, ion plating, ETP, etc. In one embodiment, the layer 8 varies from 1 μm-500 μm. Longer life cycles are generally expected when thicker protective layers are used. In one embodiment, the protective coating layer 8 has a thickness of 5 to 500 μm. In a second embodiment, the thickness is greater than or equal to about 100 μm. In yet another embodiment, the thickness is less than or equal to about 300 μm.

Overcoat Layer: In one embodiment as illustrated in FIG. 1C, the apparatus is further coated with an overcoat (or overcoating) layer 9 which is formed over the top surface of coating layer 8. In one embodiment of a susceptor as in FIGS. 1D, the overcoat (or overcoating) layer 9 directly covers the underlying substrate 6. In yet another embodiment of a susceptor as shown in FIG. 1E, the substrate 6 is first coated with the 1^{st} coating layer 8, then with the overcoating layer 9.

The top overcoat layer 9 functions as a thermal spreader and enhances the emissivity of the heater at elevated temperatures, i.e., 1500° C. or higher, and hence also increases the rate of radiative heat transfer. This in turn helps to reduce the operating heater temperature and thus prevents the early degradation of the heater. The overcoat layer 9 further functions to protect the electrode 7 from mechanical damage.

In one embodiment as illustrated in FIG. 2B, the entire heater structure is overcoated with the hermetic protective layer 9 (both top and bottom surfaces) to protect the heater structure, particularly the coating/insulating layer 8, from attacks by plasma or chemicals used in the cleaning process.

In one embodiment, the overcoat layer 9 comprises a material with a planar thermal conductivity of at least 3 times the thermal conductivity of the materials comprising the coating layer 8, hence improving the thermal uniformity on the wafer. In a second embodiment, the overcoat layer 9 comprises a material with a planar thermal conductivity of least 4 times the thermal conductivity of the overcoat layer 8. In one embodiment, the overcoat layer 9 comprises a material with a thermal conductivity of greater than 100 W/m° K. In a second embodiment, the overcoat layer 9 comprises a material with a thermal conductivity of greater than 200 W/m° K. In a third embodiment, the overcoat layer 9 comprises pyrolytic graphite (“PG”) which performs well at exceptionally high temperatures and stable up to 2200° C. Due to the nature of the deposition process by CVD, PG approaches the theoretical density of 2.25 and is essentially non-porous.

The overcoat layer 9 may be deposited by any of ETP, ion plating, CVD, PECVD, MOCVD, OMCVD, MOVPE, physical vapor deposition processes such as sputtering, reactive electron beam (e-beam) deposition, plasma spray, and combinations thereof.

The thickness of the over-coating layer 9 varies depending upon the application and the process used, e.g., CVD, ion plating, ETP, etc. In one embodiment, the thickness of layer 9 varies from 1 μm-500 μm. In a second embodiment, the protective coating layer 8 has a thickness of 5 to 500 μm. In a third embodiment, the thickness is greater than or equal to about 100 μm. In yet another embodiment, the thickness is less than or equal to about 300 μm.

In one embodiment, the overcoat layer 9 has an average surface roughness that satisfies Ra<=0.05 μm and a maximum surface roughness satisfying Rmax<=0.6 μm. In yet another embodiment, the layer has a surface roughness of Ra in a range of >0.5 μm and <3 μm. In yet another embodiment, the overcoat layer has a Scheroscope hardness in the A direction of 103 and in the C direction of 68.

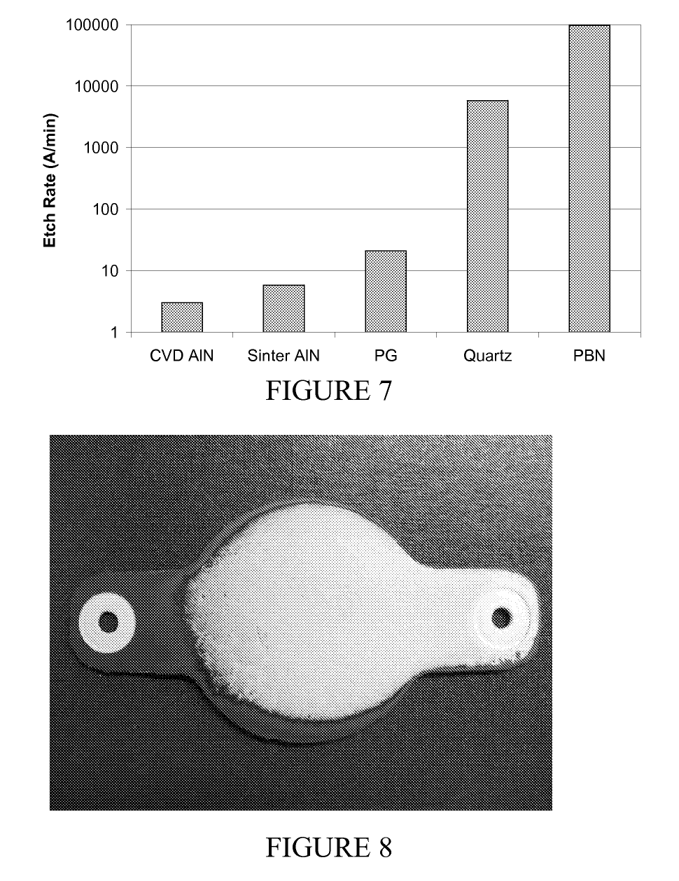

FIG. 6 is a graph illustrating the etch rate of various materials in a NF₃ environment at room temperature. In FIG. 7, the etch rate of pyrolytic graphite (PG) is compared with other materials, including pyrolytic boron nitride (pBN) and sintered aluminum nitride at 400° C. The etch rates of both CVD AlN and PG show weight gains, as compared with other materials commonly used in heaters in the prior art, i.e., quartz, pyrolytic boron nitride, sintered AlN, all show weight loss due to corrosive attacks. In FIG. 8, which is a photograph of a prior art heater comprising a pBN overcoating on a PG electrode layer, after etching for 60 minutes at 400° C. in a continuous remote NF₃ plasma, the pBN overcoating layer is removed rapidly from the underlying PG electrode. However, it is noted that the PG electrode is intact in the etching process.

Besides the corrosion problem due to etching, it should be noted that prior art heater comprising a pBN overcoat layer has a relatively soft surface and can be eroded to some extent when a silicon wafer is placed on it. The generated pBN particles will typically stick to the backside of the wafer, which can cause problems with contamination and alignment in subsequent silicon wafer processing steps. A heater of the invention is less prone to such backside problem due to the characteristics of the outer coating layer, i.e., pyrolytic graphite (“pG”) is much harder than pBN (“pyrolytic boron nitride”), AlN, etc. Furthermore, the material has very small grain size and hence even if particles are generated, they are of relatively small sizes (e.g. <0.1 micron) to cause substantial problems. Additionally, such particles would also be easy to remove in an ozone or oxygen plasma clean.

With respect to thermal spreading, because of the extremely high thermal conductivity in the in-plane direction and lower thermal conductivity in the through-plane direction, a pG coating on a heater will help “diffuse” or spread any thermal non-uniformities in the heater pattern, thus yielding a more uniform surface temperature. In addition, due to the high emissivity of pG (>0.7) versus that of pBN (˜0.4), the heater of the invention is a more effective radiative heater.

As illustrated in the Figures, the overcoat layer 9 provides an improvement over the prior art, allowing the heater to be more resistant to plasma attack and/or the fluorine containing cleaning chemistries used in many semi-conductor processing steps to clean reactor chambers, and thus extending the life of the heater. In one embodiment with a hermetic seal of a protective overcoat layer of pyrolytic graphite, the heater has an etch rate in NF₃ at 600° C. of less than 100 Angstrom/minute (A°/min). In a second embodiment, it has an etch rate in NF₃ at 600° C. of less than 50 A°/min. As the heater is less susceptible to corrosive attacks, fewer particles are expected to be released from the heater surface, there is less of a contamination problem compared with the heater of the prior art.

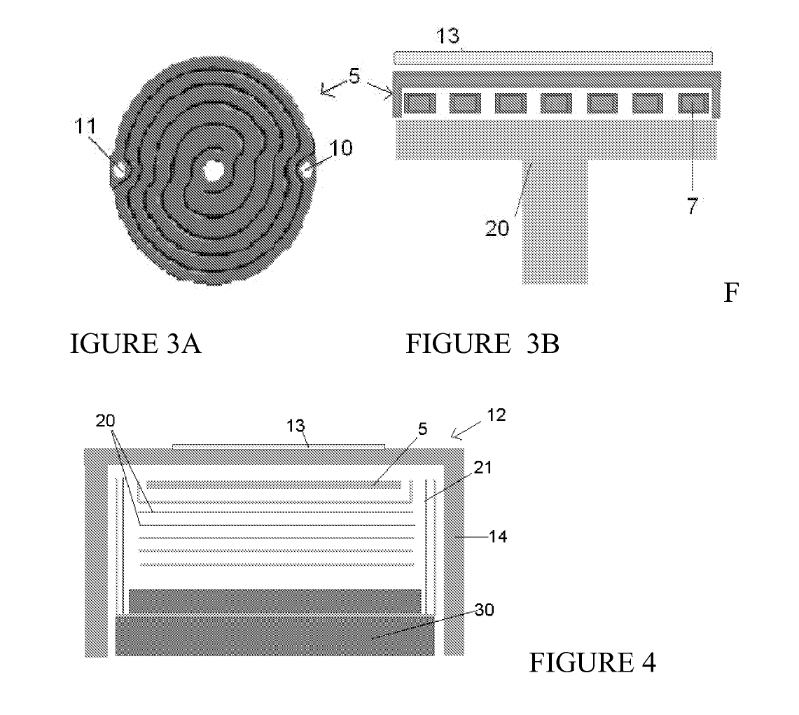

In one embodiment of a heater apparatus, the heater 5 can be of any shape/geometry suitable for the end use application. In one embodiment, it is of a circular plate shape as illustrated in FIG. 3A. In another embodiment, it may be a polygonal plate shape, a cylindrical shape, a shape of a circular plate or a cylinder with concave or convex portions. In yet another embodiment as illustrated in FIG. 3B, the heater comprises a platform to support the wafer 13 and a shaft 20 extending from and substantially transverse to the longitudinal axis of the platform. At least one heating element 7 heats up the wafer 13 supported by the platform.

Although the ramp rate of a heater in a CVD reactor is a function of: the available power, the heater configuration, the wafer diameter, and the wafer spacing; the heater of the present invention is capable of heating up at a ramp rate of at least 20° C. per min. allowing for uniform heating across the wafer surface to be heated. In one embodiment, the heater has a ramp rate of at least 30° C. per min. In one embodiment of a heater with multi-zones, the heater of the invention has a maximum temperature differential across the surface of at least 75° C. for any two points on a 300 mm diameter surface. In a second embodiment, the heater has a maximum temperature differential across the surface of at least 100° C. for a 300 mm diameter surface.

It should be noted that other components in the thermal module or CVD processing chamber require fluorine plasma resistance such as wafer carrier boats, graphite coil heaters, the focus ring, the pedestal assembly for holding the focus ring and electrostatic chuck, the gas distribution plate which defines over the electrostatic chuck, etc., can be constructed in a similar manner as the heater of the invention, i.e., with an overcoat layer comprising materials such as pG with etch resistant characteristics.

The invention is further illustrated by the following non-limiting examples.

### EXAMPLES 1 AND 2

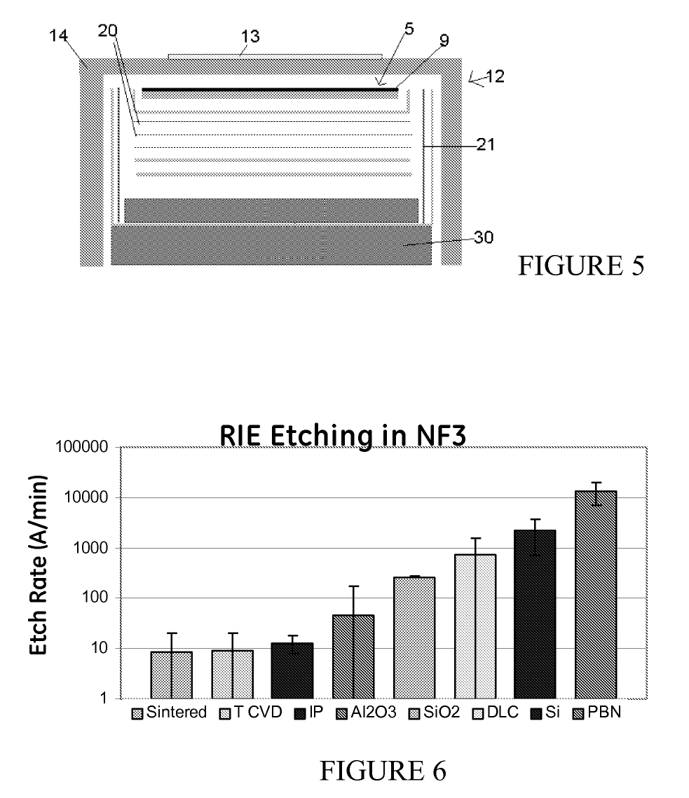

Computational fluid dynamics (CFD) calculations are carried out to model the thermal modules (heater assemblies). The first thermal module 12 employs a ceramic heater in the prior art as illustrated in FIG. 4. The same thermal module 12 employs one embodiment of the heater of the invention as illustrated in FIG. 5. The modules are to heat a single 2″ inch wafer to 1300° C. with a uniformity of around ±3° C. Uniformity requirement is extremely stringent in the case of Metal Organic Chemical Vapor Deposition (MOCVD) process. Hence, every Celsius degree variation in temperature uniformity affects the deposition process. Temperature uniformity on the wafer surface is defined as the difference between the maximum temperature and minimum temperature as measured by 9 thermocouples placed across the wafer surface.

As shown in the Figures, wafer 13 is placed on a susceptor 14 which is rotating and hence cannot be in direct contact with the heater 5. The base plate 30 comprises graphite with a PBN coating. PBN reflectors 20 comprise 2 sheets and 2 cups with thickness of 0.7 mm thick. Mo reflectors 21 comprise 3 sheets and 1 tube each having a thickness of 0.2 mm. In the thermal module 12, heater 5 heats the rotating susceptor 14 through radiation, and this heat is then transferred to the wafer by conduction.

In Example 1, the ceramic heater 5 is a radiant heater of the prior art, with a PBN core plate with a diameter of about 95 mm and a thickness of 2 mm, a thin patterned electrode of pyrolytic graphite, and an overcoating layer comprising PBN of a thickness of 15 microns. In Example 2, the prior art heater in Example 1 is further provided with a top overcoating layer comprising pyrolytic graphite of 40 μm thick.

A three dimensional model (with a mesh size of 0.87 million cells) is built for the thermal simulations of the heater assemblies of Examples 1 and 2. The Discrete Ordinates Radiation Model is used to model the surface to surface radiation between various sub-components of the thermal module 12 under two commonly experienced temperature ranges in process chambers: 1) when the ambient temperature within the process chamber is 500° C.; and 2) when the ambient temperature within the process chamber is 800° C. Additionally, user subroutines are developed to model the Joule heating within the heater and to model pyrolytic graphite electrical resistivity as a function of temperature.

Table 1 presents data obtained from the CFD model for the two examples:

TABLE 1

| | | | | | | | Max |
|---|---|---|---|---|---|---|---|
| | Heater | Heater | Heater | Ambient | Ave. T ° C. | Ave. | Heater |
| Example | Voltage V | Power kW | Resistance Ω | T ° C. | wafer | Heater T° C. | T° C. |
| 1 - A | 227.5 | 4.41 KW | 11.72 | 500 | 1297 ± 10 | 1933 | 2142 |
| 1 - B | 203.0 | 3.57 KW | 11.53 | 800 | 1298.5 ± 9 | 1851 | 2004 |
| 2 - A | 221.5 | 4.28 KW | 11.47 | 500 | 1296 ± 8.5 | 1800 | 1914 |
| 2 - B | 198.5 | 3.47 KW | 11.34 | 800 | 1299 ± 6.5 | 1743 | 1816 |

In Example 1A with the heater of the prior art, when the wafer is heated to the target temperature of around 1300° C., the average heater temperature is predicted to be around 1933° C. However, PBN surface inherently cannot withstand temperatures of more than 1800° C., so at this temperature point (of 1933° C.) and beyond, it is fully expected that the PBN surface of the heater in the prior art to start cracking causing the heater to malfunction. In Example 1B also with the heater of the prior art and with an ambient temperature of 800° C., when the heater is heated to a target temperature of 1300° C., the average heater temperature reaches 1851° C., with the same effects expected on the heater of the prior art with the PBN surface not being able to withstand temperatures of >1800° C.

In Examples 2A and 2B using the heater of the invention, the wafer is again heated to the same target temperature of 1300° C. In Example 2A, an average required heater temperature of 1800° C. is predicted. The model shows a clear improvement in the thermal uniformity on the wafer surface due to the excellent better planar thermal conductivity of the pyrolytic graphite topcoat. The improvement is in the order of 2-3° C., which is still very critical in MOCVD processes due to stringent uniformity requirement of such processes. It should be noted that the 2-3° C. change results in an improvement of the temperature uniformity of the wafer by around 15-20%.

In example 2B, the model predicts an average required heater temperature of about 1743° C., which is under the critical operating temperature of the pBN top-coated heaters of the prior art. The model further predicts improvement in the thermal uniformity on the wafer surface in the order of 2-3° C.

The CFD data demonstrates that a top overcoating layer of PG material on a PBN heater is particularly suitable for high temperature applications such as MOCVD. A heater coated with an over-coating material such as PG, can operate about 100-150° C. below the heater without a PG over-coat, and both will still achieve the same susceptor temperature. This difference in the heater operating temperatures is very critical especially when the heater needs to operate around the peak permissible temperature of 1800° C.

### EXAMPLE 3

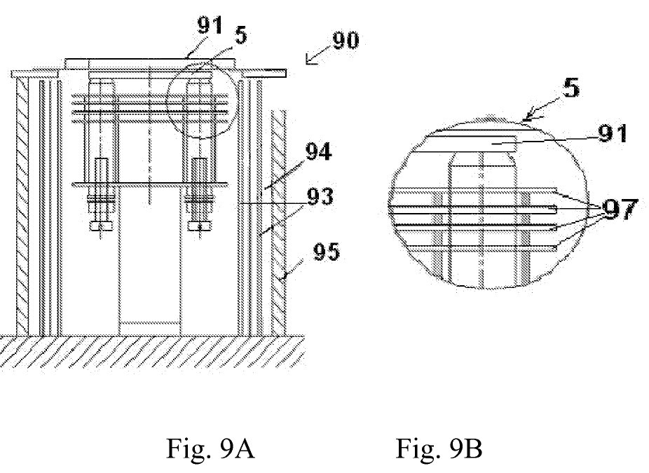

In this example, a radiant ceramic heater of the prior art is experimentally tested in an enclosed thermal module 90 as illustrated in FIGS. 9A-9B. In 9A, the ceramic heater 5 has a pBN core plate with a diameter of about 40 mm and a thickness of 2 mm, a thin patterned electrode of pyrolytic graphite, and an overcoating layer comprising pBN of a thickness of 0.15 mm. The enclosed thermal module 90 has an ambient pressure of 30 pa (close to vacuum condition). The heater 5 is surrounded by concentric cylinder tubes (90 mm in diameter) comprising pBN 93, Mo 94, and graphite 95, which function as radiation shields. In FIG. 9B, a stack of reflector plates 97 comprising pBN and Mo are placed below the heater to help conserve the heat by reflecting by towards the graphite susceptor 91, which is positioned 3-5 mm above the heater top surface. The susceptor having a diameter of 55 mm is heated only by thermal radiation.

A wafer is placed on the susceptor 91, which rotates and cannot be in direct contact with the heater. In the experimental setup, 2 thermocouples are used, one to measure the heater center temperature and the other to measure the susceptor center temperature. In the experiment, the heater power is gradually increased and the heater temperature starts ramping from the room temperature of 25° C., with the heater power being increased till about 1170 Watts (Heater voltage=65 V and Heater Current=18 A). At this power setting, the measured heater temperature is 1700° C. and the measured susceptor temperature is 1100° C.

### EXAMPLE 4

This is a duplicate of Example 3, except that a heater of the present invention is used. In this example, a 40 mm diameter ceramic heater with a pBN core plate with a diameter of about 40 mm and a thickness of 2 mm, a thin patterned electrode of pyrolytic graphite, and an overcoating layer comprising PBN of a thickness of 0.15 mm. Over this coating, the heater is further provided with a top overcoating layer of pyrolytic graphite of about 40 μm thick.

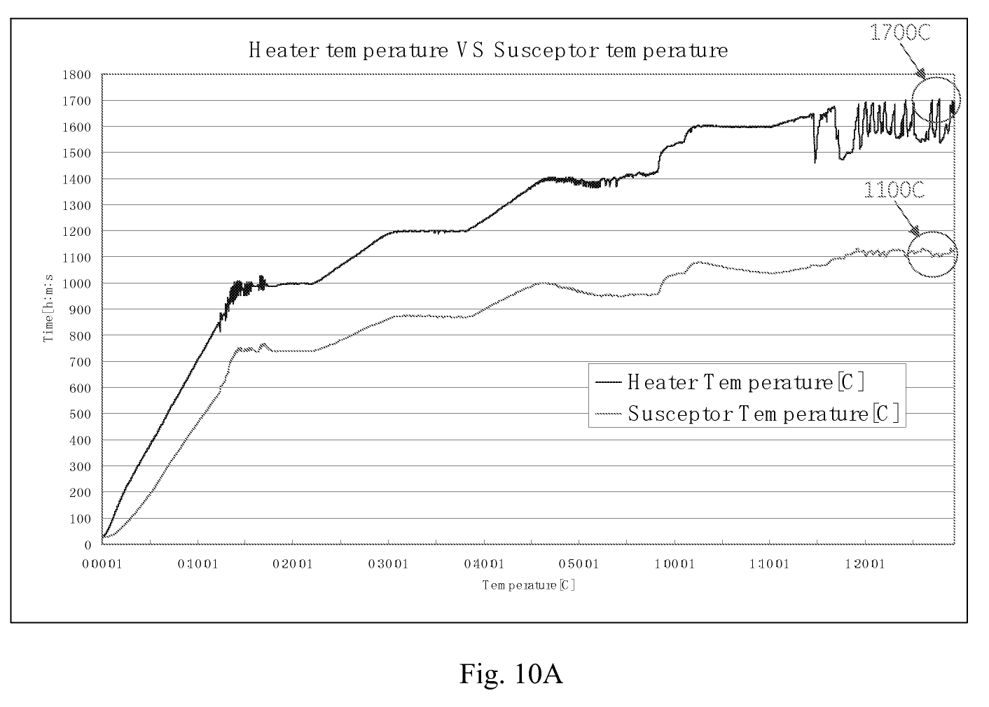

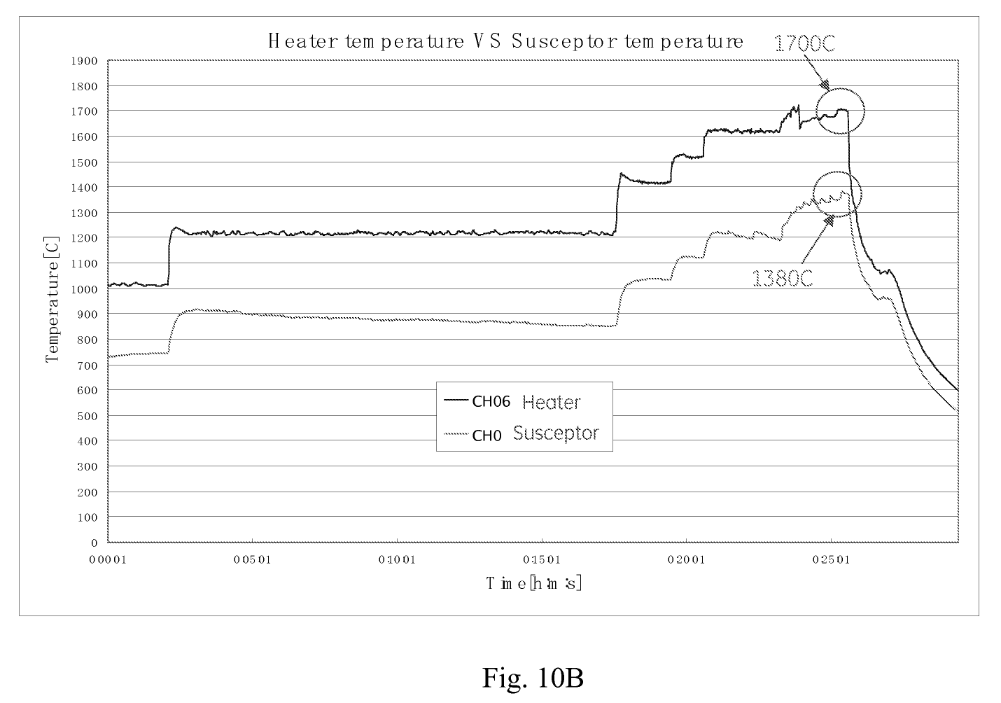

Table 2 presents data obtained from the operation of the thermal modules of Examples 3 and 4 in heating the susceptor when the heater is steadily maintained at 1700° C. Data is also illustrated in FIG. 10A-10B comparing the ramping tests of the two heaters.

TABLE 2

| Example | Heater Type | Susceptor T ° C. | Heater T° C. |
|---|---|---|---|
| 3 | PBN Heater | 1100 | 1700 |
| 4 | PG Overcoated PBN Heater | 1380 | 1700 |

As illustrated in Table 2, when both heaters are set to the same T of 1700° C., the susceptor T for the heater of the invention (Example 4—PG overcoated PBN heater) is ˜300° C. higher than the susceptor T obtained by the prior art heater (Example 3—PBN heater). A thermal module has more radiation efficiency when one can achieve higher susceptor temperature for the same set heater temperature, and this is what has been observed.

Another way to view this radiation efficiency is that the heater of the invention can afford to operate at a lower temperature (e.g., less than 1500° C. or ˜1400° C.) to match the susceptor temperature of 1100° C. of the prior art heater, as opposed to the prior art heater, which needs to operate at 1700° C. Thus, to achieve the same target wafer temperature, the heater of the present invention can operate at a lower temperature than the prior art heater. This factor further helps prolong the life of the ceramic heater, as with a lower operating temperature.

It has also been observed that the heater of invention also demonstrates a more even/uniform temperature profile on the susceptor surface, having about 15-20% improvement over the prior art heater.

### EXAMPLE 5

In this experiment, after a heater coated with pyrolytic graphite is exposed to remote NF3 plasmas at temperatures in the 400-600° C. range, a net weight gain is observed. The weight gain is roughly 0.02 g per 1 hour of continuous remote NF3 plasma exposure for a sample with an exposed area of around 151 Cm². From an Energy Dispersive Spectroscopy (EDS) analysis of the surface of NF₃ etched PG samples; the weight gain is found to be from the formation of a fluorocarbon reaction layer on the surface of the PG. From further analysis with X-Ray Photoelectron Spectroscopy (XPS) of a high-resolution C(1s) spectrum, it is found that the fluorine reaction layer on the PG surface mainly consists of CF₂. After heating in vacuum, the majority of fluorocarbon evaporates.

From the experiment, the actual amount of PG consumed per unit time in the formation of the fluorocarbon layer can be computed. The results are illustrated in Table 3 below. As shown, the pyrolytic graphite coating layer shows a 0.02 g weight gain per 1 hr for a 151 Cm² sample, corresponds to a PG consumption rate of around 0.19 μ per hour (or 31 A/min). This compares to an etch rate for pyrolytic Boron Nitride of ˜1E6 A/min.

TABLE 3

| Sample | C | F | O |
|---|---|---|---|
| Pyrolytic graphite | 99.6 | 0 | 0.4 |
| PG − Etch | 50.2 | 47.8 | 1.4 |
| PG − Etch + Anneal | 90.6 | 8.8 | 0.5 |

### EXAMPLE 6

When one of the samples from Experiment 5 is analyzed by dynamic XPS, i.e. depth analysis via cycling between argon sputtering and XPS analysis, it is found that the fluorocarbon layer that had build up on the pyrolytic graphite coating layer in 60 min. of continuous NF₃ plasma exposure, is thicker than 500 Angstrom. After heating, a small amount of F (<10%) is found to be in the pyrolytic graphite.

### EXAMPLE 7

A sample from Experiment 5 (after etching) is exposed to a temperature of 700° C. for 2 hours in vacuum, it is found that the fluorocarbon layer thickness is substantially reduced. The results are also confirmed by EDS and XPS analyses. This indicates that the fluorocarbon layer only is stable at high temperature (400-600° C.) if a high enough concentration of atomic fluorine is in the gaseous phase near the surface of the sample. If the fluorine concentration drops, then the evaporation of the fluorocarbon layer is favored.

### EXAMPLE 8

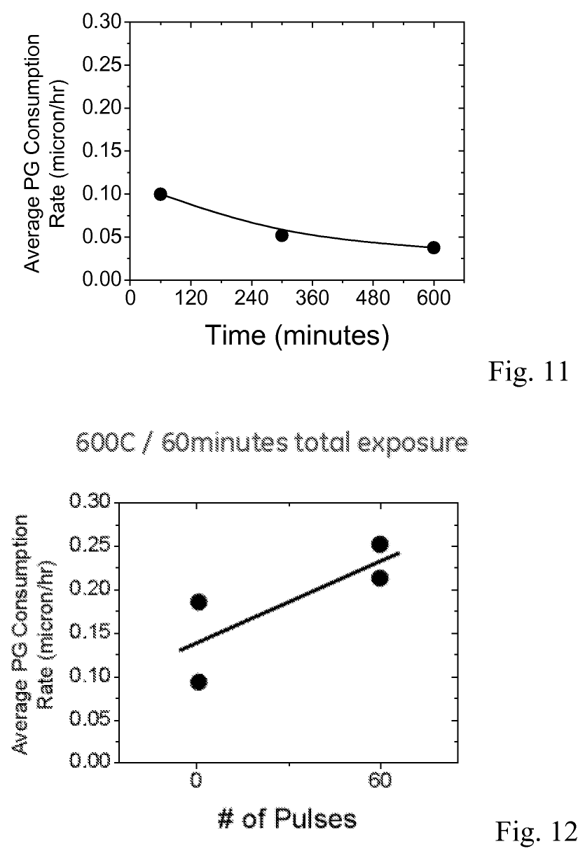

Experiment 5 is repeated and one sample is etched continuously for 5 hours (instead of 1 hour) at 400° C. The average PG consumption rate (etch rate) is lower than previously experienced in Experiment 5 (1 hour experiment) as illustrated in FIG. 11. The experiment illustrates that initially when there is only a native PG surface, the fluorination will happen rapidly. However, after some thickness of fluorocarbon layer has been built up, the fluorine will need to diffuse through this fluorocarbon layer before it finds new pyrolytic graphite that can be fluorinated. After some point, the fluorination rate will become fluorine diffusion rate limited.

### EXAMPLE 9

This experiment is to probe if the effects of fluorine diffusion rate limit PG fluorination further. A sample with a PG coating is etched for 1 minute at 600° C., then the plasma is switched off for 1 minute while keeping the PG at 600° C. The cycle is repeated 60 times to ensure that the total plasma exposure time is 1 hour. The average PG consumption rates of this experiment are compared to a sample that previously etched continuously for 60 minutes. The results as illustrated in FIG. 12 show that the average etch rate is higher in the case of pulsed etching than in the case of continuous etching.

This is explained as follows. In the pulsed etching case the overcoat layer initially builds up a fluorocarbon layer during the 1 minute that the NF₃ plasma is on. Then once the NF₃ plasma is off, the earlier formed fluorocarbon layer partially evaporates (similar to Example 7). Once the plasma is turned on again, the fluorine sees a thinner fluorocarbon layer, diffuses faster and thus consuming the PG faster. While in the case of continuous etching, the fluorocarbon layer continues to grow over time and thus slowing down the PG fluorination rate. So for the same total exposure time, the pulsed experiment etches faster. However, the fluorocarbon evaporation rate is apparently slow enough to only cause the pulsed experiment to be marginally faster.

### EXAMPLE 10

Comparing the continuous NF₃ plasma etch rates of PG at 400° C. and 600° C. (see FIGS. 11 and 12), there is only a relatively small increase in etch rate. Additionally, the etch rate at 600° C. is still well below 50 A/min. As shown, the heater of this invention would allow one to clean the reactor while keeping the heater at 600° C.

### EXAMPLE 11

In the event that it is not desirable to have a fluorocarbon layer in contact with the backside of the wafer, after cleaning and before bringing a new wafer into the reactor, a short deposition run is conducted in the wafer chamber to season the chamber and deposit a thin coating on the walls and the heater. Alternatively after cleaning, the reactor chamber is flushed with a very brief oxygen pulse containing plasma etch to remove the fluorocarbon layer off the surface of the substrate holder of the invention. In another example, the heater assembly is left in vacuum for short amount of time to evaporate the fluorocarbon layer off the surface automatically.

This written description uses examples to disclose the invention, including the best mode, and also to enable any person skilled in the art to make and use the invention. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

All citations referred herein are expressly incorporated herein by reference.

1. An apparatus for use in a wafer processing chamber, the apparatus comprising:
a base substrate comprising one of graphite; refractory metals, transition metals, rare earth metals and alloys thereof; a sintered material including at least one of oxide, nitride, carbide, carbonitride or oxynitride of elements selected from a group consisting of B, Al, Si, Ga, refractory hard metals, transition metals; oxide, oxynitride of aluminum; and combinations thereof;
wherein the base substrate is coated with an over-coating layer having a thermal conductivity greater than 100 W/m° K.

2. The apparatus of claim 1, wherein the apparatus is a heater, which further comprises:
a heating element comprising pyrolytic graphite superimposed on the base substrate;
a first layer coating the heating element and the base substrate, the layer comprises at least one of a nitride, carbide, carbonitride or oxynitride of elements selected from a group consisting of B, Al, Si, Ga, refractory hard metals, transition metals, and combinations thereof;
wherein the first layer coating is coated with the over-coating layer having a thermal conductivity greater than 100 W/m° K.

3. The apparatus of claim 2, wherein the over-coating layer has a planar thermal conductivity of at least 3 times the planar thermal conductivity of the first coating layer.

4. The heater of claim 1, wherein the overcoat layer comprises a material having planar thermal conductivity of at least 4 times the planar thermal conductivity of the first outer coating layer.

5. The heater of claim 2, wherein the first outer coating layer comprises at least one of pyrolytic boron nitride, aluminium nitride (AlN), aluminium oxide, aluminium oxynitride, silicon nitride, or complexes thereof.

6. The apparatus of claim 1, wherein the apparatus is a susceptor, the base substrate comprises graphite, and the over coating layer comprises pyrolytic graphite.

7. The apparatus of claim 1, wherein the overcoat layer comprises a material having a thermal conductivity greater than 200 W/m° K.

8. The heater of claim 2, wherein the overcoat layer comprises a material having a radiation efficiency above 70% at a temperature greater than 1500° C.

9. The heater of claim 2, wherein the overcoat layer comprises a material having a radiation efficiency above 80% at a temperature greater than 1500° C.

10. The apparatus of claim 1, wherein the overcoat layer comprises pyrolytic graphite (“PG”).

11. The apparatus of claim 1, wherein the overcoat layer is deposited by any of ETP, ion plating, ion plasma plating, CVD, PECVD, MOCVD, OMCVD, MOVPE, e-beam deposition, plasma spray, and combinations thereof.

12. The apparatus of claim 1, characterized by having an etch rate in NF3 at 600° C. of less than 100 A/min.

13. The apparatus of claim 10, characterized by an etch rate in NF3 at 600° C. of less than 50 A/min.

14. The apparatus of claim 1, wherein the apparatus is a heater capable of heating up at a ramp rate of at least 20° C. per min.

15. The apparatus of claim 1, wherein the apparatus is a heater capable of heating up at a ramp rate of at least 30° C. per min.

16. The heater apparatus of claim 2, wherein:
the base substrate comprises graphite;
the heating element superimposed on the base substrate comprises pyrolytic graphite,
the first outer coating layer comprises at least one of boron nitride and aluminum nitride;
the over coating layer comprises pyrolytic graphite.

17. The apparatus of claim 1, wherein the over coating layer has a thickness between 1 μm-500 μm.

18. The apparatus of claim 15, wherein the over coating layer has a thickness between 5 to 300 μm.

19. The apparatus of claim 16, wherein the over coating layer has a thickness less than 100 μm.

20. A plasma processing chamber for processing at least a semiconductor wafer, the plasma processing chamber comprising:
at least a ceramic heater for heating the wafer;
gas distribution plate defined over the electrostatic chuck;
a pedestal for holding the electrostatic chuck;
a source of cleaning gas communicating selectively with the chamber;
wherein at least one of the heater, the gas distribution plate, and the pedestal has a surface coated with a over coating layer comprising pyrolytic graphite, and wherein
the source of cleaning gas comprises NF₃ and Cl₂.

21. The plasma processing chamber of claim 18, wherein the heater is coated with the over coating layer comprising pyrolytic graphite, and wherein the heater comprises:
a base substrate comprising one of graphite; refractory metals, transition metals, rare earth metals and alloys thereof; a sintered material including at least one of oxide, nitride, carbide, carbonitride or oxynitride of elements selected from a group consisting of B, Al, Si, Ga, refractory hard metals, transition metals; oxide, oxynitride of aluminum; and combinations thereof;
a heating element comprising pyrolytic graphite superimposed on the base substrate,
a first outer coating comprising comprises at least one of a nitride, carbide, carbonitride or oxynitride of elements selected from a group consisting of B, Al, Si, Ga, refractory hard metals, transition metals, and combinations thereof;
wherein the pyrolytic graphite over coating layer protects the underlying first coating layer, heating element, and base substrate from the cleaning gas, for the heater to have an etch rate in NF3 at 600° C. of less than 100 A/min.

22. The plasma processing chamber of claim 19, wherein the heater has an etch rate in NF3 at 600° C. of less than 50 A/min.
